(19) United States
(12) Patent Application Publication
(10) Pub. No.: US 2017/0133242 A1
(43) Pub. Date: May 11, 2017

(54) METHOD OF PRIMING AND DRYING SUBSTRATES

(71) Applicant: Akrion Systems LLC, Allentown, PA (US)

(72) Inventors: Ismail Kashkoush, Orefield, PA (US); David Magniarini, Center Valley, PA (US); Carlos M. Ruiz, Breinigsville, PA (US)

(21) Appl. No.: 15/177,643

(22) Filed: Jun. 9, 2016

Related U.S. Application Data
(63) Continuation of application No. 13/092,661, filed on Apr. 22, 2011, now abandoned.
(60) Provisional application No. 61/326,756, filed on Apr. 22, 2010.

(51) Int. Cl. H01L 21/67; H01L 21/02

(52) U.S. Cl. CPC H01L 21/67034; H01L 21/02057

(57) ABSTRACT

A method of priming and drying substrates having high-aspect ratio trenches. In one aspect, the method comprises: a) supporting at least one substrate having high-aspect ratio trenches in a process chamber having a gaseous atmosphere; b) sealing the process chamber; c) vacuuming the process chamber to achieve a first sub-atmospheric pressure within the process chamber; d) introducing a wetting solution into the process chamber while maintaining the process chamber at a second sub-atmospheric pressure until the substrate is immersed in the wetting solution; e) restoring the process chamber to atmospheric pressure while the substrate remains immersed in the wetting solution; and f) removing the substrate from the wetting solution.

### CROSS-REFERENCE TO RELATED APPLICATIONS

This application claims priority as a continuation to U.S. patent application Ser. No. 13/092,661, filed Apr. 22, 2011, which claims priority to U.S. Provisional Patent Application No. 61/326,756, filed on Apr. 22, 2010, the entireties of which are incorporated herein by reference.

### FIELD OF THE INVENTION

The present invention relates to a method of preparing substrates for further processing by placing the substrates in a process chamber having sub-atmospheric vacuum pressure and introducing a wetting solution into the process chamber. The invention also relates to a method of drying substrates by placing the substrates in a process chamber having sub-atmospheric vacuum pressure and introducing a heated gas into the process chamber.

### BACKGROUND OF THE INVENTION

In the semiconductor industry, effectively removing all particles and fluids from the surface of a wafer or substrate is of utmost importance. If particles and fluids are left on the surface of a wafer, the wafer will not operate properly. Furthermore, removing particles from semiconductor wafers during the manufacturing process is a critical requirement to producing quality profitable wafers. While many different systems and methods have been developed over the years to remove particles from semiconductor wafers, many of these systems and methods are undesirable because they damage the wafers or are simply ineffective. Thus, the removal of particles from wafers must be balanced against the amount of damage caused to the wafers by the processing method and/or system. It is therefore desirable for a processing method or system to be able to break particles free from the delicate semiconductor wafer without resulting in damage to the devices on the wafer surface.

As semiconductor wafers have gradually decreased in size, the need to maintain purity on the wafers has become more important. Because wafers used today may be as small as one millimeter or less in thickness, even the tiniest of particles stuck to the wafer surface may cause irreparable damage to the wafer. Therefore, maintaining a pure semiconductor wafer surface with no particles or other impurities trapped within trenches or vias on the wafer surface is vastly important.

During the manufacturing process, semiconductor wafers may go through hundreds of processing steps. It is important to prepare the wafer prior to beginning the manufacturing process that results in the production of the desired semiconductor integrated circuit in order to ensure proper surface exposure of the wafer during the subsequent processes. Thus, a need exists for a method and/or system of effectively preparing a wafer prior to the manufacturing process.

Another important concept in the semiconductor industry is that of wafer drying. After completion of the manufacturing steps, it is necessary to completely dry the wafer so as not to leave any fluid streaks on the wafer surface. It is also necessary to ensure that all particles and fluid are removed from the wafer surface and from the tiny, yet deep wells that are formed into the wafer surface. Thus, a need exists for a method and/or system that effectively dries a wafer and removes all fluid residues after the wafer is treated during the manufacturing process.

### SUMMARY OF THE INVENTION

Exemplary embodiments of the invention are directed to a method of priming substrates having high-aspect ratio trenches for further processing and a method of drying substrates having high-aspect ratio trenches. Both the priming and drying methods occur under vacuum pressure within a process chamber. During the priming method, a wetting solution is introduced into the process chamber while the process chamber is under vacuum pressure. During the drying method, a heated gas is introduced into the process chamber while the process chamber is under vacuum pressure. Typically, there are many process sequences that take place after the priming method and prior to the drying method.

In one embodiment, the invention can be a method of priming substrates having high-aspect ratio trenches for further processing, the method comprising: a) supporting at least one substrate having high-aspect ratio trenches in a process chamber having a gaseous atmosphere; b) sealing the process chamber; c) vacuuming the process chamber to achieve a first sub-atmospheric pressure within the process chamber; d) introducing a wetting solution into the process chamber while maintaining the process chamber at a second sub-atmospheric pressure until the substrate is immersed in the wetting solution; e) restoring the process chamber to atmospheric pressure while the substrate remains immersed in the wetting solution; and f) removing the substrate from the wetting solution.

In another embodiment, the invention can be a method of drying substrates having high-aspect ratio trenches comprising: a) supporting at least one substrate having high-aspect ratio trenches in a process chamber having a gaseous atmosphere; b) sealing the process chamber; c) vacuuming the process chamber to achieve a first sub-atmospheric pressure within the process chamber, the first sub-atmospheric pressure being equal to or less than 10 Torr; and d) introducing a heated gas into the process chamber while maintaining the process chamber at a second sub-atmospheric pressure.

In a further embodiment, the invention can be a method of processing substrates having high aspect ratio trenches, the method comprising: a) supporting at least one substrate having high-aspect ratio trenches in a first process chamber having a gaseous atmosphere; b) sealing the first process chamber; c) vacuuming the first process chamber to achieve a first sub-atmospheric pressure within the first process chamber; d) introducing a wetting solution into the process chamber while maintaining the first process chamber at a second sub-atmospheric pressure until the substrate is immersed in the wetting solution; e) restoring the process chamber to atmospheric pressure while the substrate remains immersed in the wetting solution; f) removing the substrate from the wetting solution; g) performing at least one process sequence to the substrate; h) removing bulk moisture from the substrate; i) supporting the substrate in a second process chamber having a gaseous atmosphere; j) sealing the second process chamber; k) vacuuming the second process chamber to achieve a third sub-atmospheric pressure within the second process chamber; and l) introducing a heated gas into the process chamber while maintaining the process chamber at a fourth sub-atmospheric pressure, thereby removing residual moisture from the high aspect ratio trenches of the substrate.

Further areas of applicability of the present invention will become apparent from the detailed description provided hereinafter. It should be understood that the detailed description and specific examples, while indicating the preferred embodiment of the invention, are intended for purposes of illustration only and are not intended to limit the scope of the invention.

### BRIEF DESCRIPTION OF THE DRAWINGS

FIG. 1 is a schematic representation of a vacuum priming chamber for priming a substrate according to an embodiment of the present invention;

FIG. 2 is a schematic representation of a vacuum drying chamber for drying a substrate according to an embodiment of the present invention.

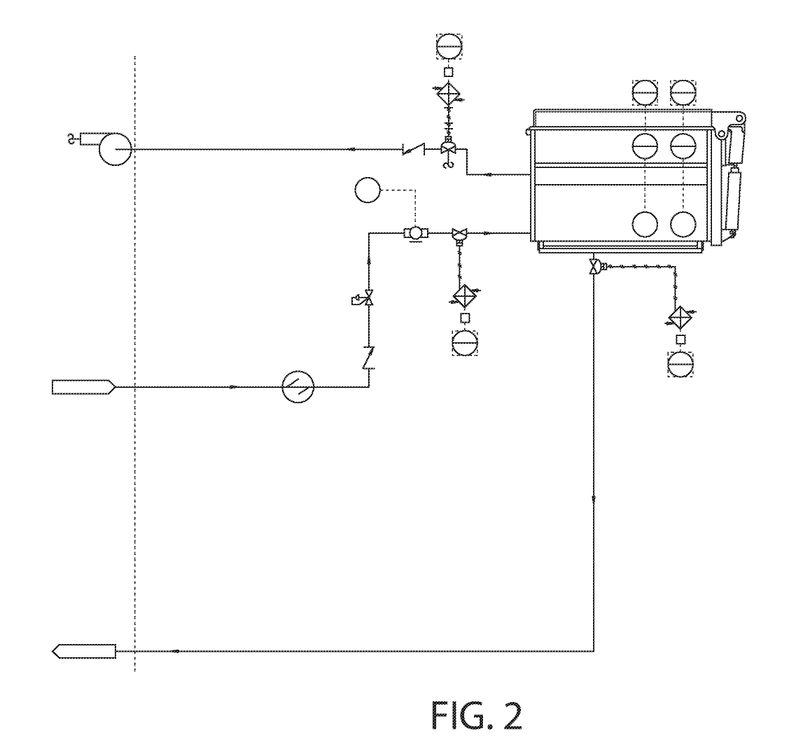

### DETAILED DESCRIPTION OF THE INVENTION

The following description of the preferred embodiment(s) is merely exemplary in nature and is in no way intended to limit the invention, its application, or uses.

The description of illustrative embodiments according to principles of the present invention is intended to be read in connection with the accompanying drawings, which are to be considered part of the entire written description. In the description of the exemplary embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “left,” “right,” “top,” “bottom,” “front” and “rear” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” “secured” and similar refer to a relationship wherein structures are secured or attached to one another either directly or indirectly through intervening structures, as well as both movable or rigid attachments or relationships, unless expressly described otherwise. Moreover, the features and benefits of the invention are described by reference to the exemplary embodiments illustrated herein. Accordingly, the invention expressly should not be limited to such exemplary embodiments, even if indicated as being preferred. The discussion herein describes and illustrates some possible non-limiting combinations of features that may exist alone or in other combinations of features. The scope of the invention is defined by the claims appended hereto.

For purposes of this invention, it is to be understood that the term substrate is intended to mean any solid substance onto which a layer of another substance is applied and that is used in the solar or semiconductor industries. This includes, without limitation, silicon wafers, glass substrates, fiber optic substrates, fused quartz, fused silica, epitaxial silicon or the like. The terms substrate and wafer may be used interchangeably throughout the description herein. Furthermore, it should be understood that the invention is not limited to any particular type of substrate and the methods described herein may be used for the preparation and/or drying of any flat article.

Semiconductor substrates go through a multitude of steps during the manufacturing process that can take between six and eight weeks to complete. These manufacturing steps take place in highly specialized facilities known as fabs and include cleanrooms, which are rooms that have an environment with an extremely low level of pollutants such as dust, airborne microbes, aerosol particles and chemical vapors. It is important to ensure that prior to being treated the substrate is properly prepared or primed to ensure proper surface exposure for the subsequent processes.

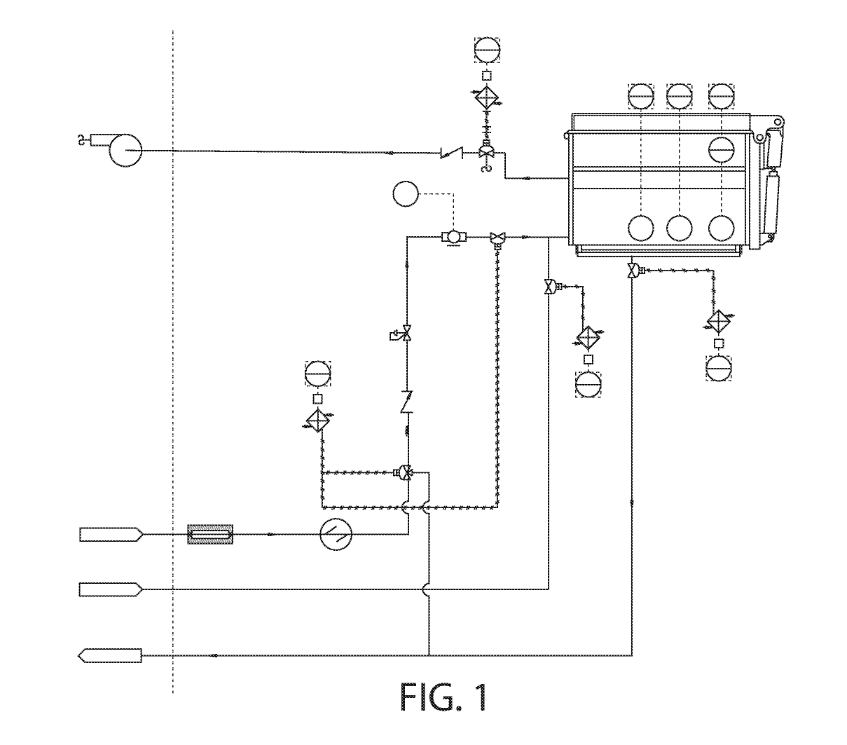

Referring to FIG. 1, a method of priming substrates having high-aspect ratio trenches (or via holes) will be described. Prior to describing the actual steps that encompass the method of priming, the various components illustrated in FIG. 1 will be described.

In semiconductor technology, trenches or via holes are formed on the substrate surfaces via dry etching processes, such as a plasma dry etch. The trenches have an aspect ratio, which is the ratio of the depth or thickness of the substrate to the width of the trenches. In certain embodiments of the present invention, the trenches of the substrate have high aspect ratios with a depth-to-width ratio that is greater than 3:1. In certain other embodiments the trenches of the substrate have a high aspect ratio with a depth-to-width ratio that is greater than 5:1. The dry etching process used to create the trenches results in the formation of residues in the trenches. Thus, the trenches are tiny, deep wells within the substrate surface and they become contaminated with residue and fluid that must be removed prior to treating the substrate. Of course, the invention is not to be limited by the aspect ratio of the trenches unless so specified in the claims.

Typical semiconductor substrate thicknesses are in the range of 500 microns to 1000 microns, although they can be less than 500 microns in certain circumstances. As the diameter of the standard semiconductor substrates continues to increase, the thickness has also been increasing. Presently, the current state-of-the-art fab operates with 300 mm diameter substrates with a 775 micron thickness, with the next standard projected to be 450 mm diameter substrates with a 925 micron thickness. The inventive method described herein is not limited to being used with 300 mm diameter substrates but can instead be used with substrates of any size.

FIG. 1 illustrates a process chamber 100 for supporting at least one substrate having the high-aspect ratio trenches as described above. The process chamber 100 is preferably sized and configured to hold and support a batch of substrates for preparation and/or priming. The process chamber 100 is a standard 10 gallon tank, but it can be larger or smaller as desired. In certain embodiments, the process chamber 100 can hold and support between 25 and 200 substrates, in certain other embodiments the process chamber 100 can hold and support between 30-100 substrates, and in still other embodiments the process chamber 100 can hold and support between 45-65 substrates. However, the invention is not so limited and in still other embodiments the process chamber 100 may be sized and configured to hold a single wafer for preparation and/or priming.

The process chamber 100 comprises a lid 101 that can be raised for loading the substrates into the process chamber 100 and lowered to seal the process chamber 100. The lid 101 is operably coupled to the process chamber 100 in any manner known in the art. The lid 101 may enable top-loading of the substrates into the process chamber 100 or side-loading of the substrates into the process chamber 100. When the lid 101 is lowered to seal the process chamber 100, the process chamber 100 becomes a hermetically sealed vessel capable of sustaining a vacuum. The process chamber 100 may be of any shape or configuration that is capable of being loaded with the substrates and used as a vacuum vessel when the lid 101 is attached thereto thereby creating an enclosed space or cavity.

A vacuum pump 110 is operably coupled to the process chamber 100 by a pump line 118 for removing gas from the process chamber 100 to create a sub-atmospheric pressure within the process chamber 100. The vacuum pump 110 may be any type of pump that is known in the art and capable of achieving the sub-atmospheric pressure levels described herein below. In certain embodiments, the vacuum pump 110 is capable of achieving a vacuum inside of the process chamber 100 whereby the pressure or vacuum level is less than 10 Torr. In certain other embodiments, the sub-atmospheric pressure that is attained within the process chamber 100 is between 1 Torr and 7 Torr.

Positioned along the pump line 118 between the vacuum pump 110 and the process chamber 100 is a valve 119. The valve 119 can be opened to enable the vacuum pump 110 to operate and remove gas from the process chamber 100 or closed to prevent the vacuum pump 110 from operating. Operation of the valve 119 can be performed manually or by operable connection to a controller (not illustrated), such as a properly programmed processor, that monitors the pressure within the process chamber 100 and automatically opens and closes the valve 119 as needed in order to achieve or maintain a particular pressure level. All of the valves described herein can be any type of valve known to persons skilled in the art, such as, for example without limitation, a pneumatically actuated diaphragm valve, a manual valve, a hydraulic valve, a solenoid valve, a motorized valve, a gate valve, a plug valve or the like. The specific type of valve used is not to be in any way limiting of the present invention.

In order to effectively monitor the pressure level in the process chamber 100, a pressure sensor 111 is operably coupled to the process chamber 100. In certain embodiments, the pressure sensor 111 is operably coupled to a monitor or other display 112 for visually displaying the pressure within the process chamber 111. Thus, a user can visualize the pressure on the display 112 and manually open and close the valve 119 in order to maintain or achieve a desired sub-atmospheric pressure in the process chamber 100. Of course, other methods of displaying the pressure of the process chamber 100 to a user may be utilized with the present invention. In certain embodiments, the pressure sensor 111 is operably coupled to the controller for automatically carrying out the process. Thus, the pressure sensor 111 will transmit data that corresponds to the pressure within the process chamber 100 to the controller so that the controller can determine when to open and close the valve 119 as described above. The controller will automatically send instructions to open or close the valve 119 to start or stop operation of the vacuum pump 110 in response to the data received by the pressure sensor 111.

The pressure sensor 111 can be coupled to the process chamber 100 either externally or internally. As will be better understood from the description below, when the pressure sensor 111 is positioned within the process chamber 100, the pressure sensor 111 is positioned above a location in the process chamber 100 that is aligned with a maximum liquid level 150. The maximum liquid level 150 is the highest point in the process chamber 100 that the liquid level, and more particularly the wetting solution level, will rise to. Thus, it is important that the pressure sensor 111 remain above the maximum liquid level 150 so that it can accurately measure the gaseous pressure within the process chamber 100. The maximum liquid level 150 will be described in more detail below during the discussion of the method of priming the substrates.

A wetting solution reservoir 120 (or other source) is operably coupled to the process chamber 100 via a wetting solution supply line 125. The wetting solution reservoir 120 contains an amount of the wetting solution that will be introduced into the process chamber 100 during the priming method. The wetting solution can be, for example without limitation, deionized water (DIW), standard clean 1 (SC1), standard clean 2 (SC2), hydrofluoric acid (HF), ozonated water or combinations thereof. Of course, the wetting solution is not to be limited by the particular solutions described above and the wetting solution can be any other type of solution that is suitable for preparing, priming or cleaning substrate surfaces.

Positioned along the wetting solution supply line 125 is a degassifier 121 for degasifying the wetting solution, a heater 122 for heating the wetting solution as desired and a flowmeter 123 for controlling the flow rate of the introduction of the wetting solution into the process chamber 100. The flow and dispersion of the wetting solution into the process chamber 100 is strictly controlled by the flowmeter 123 in order to allow for uniform coverage of the surface of the substrate while preventing thermal shock to the substrates. Furthermore, the wetting solution can be heated by the heater 122 as desired in order to prevent the substrate from experiencing thermal shock. Thus, heating the wetting solution can prevent the substrate from cracking or otherwise becoming damaged as a result of a rapid temperature change as the wetting solution is introduced into the process chamber 100. The exact temperature that the wetting solution is heated to is determined in order to optimize the conditions within the process chamber 100 while preventing thermal shock.

Furthermore, valves 124, 126 are positioned along the wetting solution supply line 125. Of course, in certain embodiments one of the valves 124, 126 may be omitted so that there is only one valve positioned along the wetting solution supply line 125. The valves 124, 126 can be opened to enable the wetting solution to flow from the wetting solution reservoir 120 and into the process chamber 100 and closed to prevent the wetting solution from flowing from the wetting solution reservoir 120 into the process chamber 100. Control of the valves 124, 126 may be performed manually or by the controller. In order to control the valves 124, 126 with the controller, the valves 124, 126 must be operably coupled to the controller.

In order to monitor the level of the liquid, and specifically the level of the wetting solution within the process chamber 100, a liquid level sensor 113 is operably coupled to the process chamber 100. The reading from the liquid level sensor 113 is displayed on a display 114 that is positioned external to the process chamber 100. In certain embodiments, the liquid level sensor 113 is operably connected to the controller. As such, the liquid level sensor 113 will transmit data corresponding to the level of the liquid in the process chamber 100 to the controller so that the controller can automatically open and close the valves 124, 126 as needed to ensure proper coverage of the substrates with the wetting solution while preventing overflowing of the process chamber 100. Additionally, in order to monitor the temperature within the process chamber 100, a temperature sensor 115 is operably coupled to the process chamber 100. The reading from the temperature sensor 115 is displayed on a display 116 that is positioned external to the process chamber 100. The temperature sensor 115 can also be operably coupled to the controller for automatically controlling the temperature within the process chamber 100.

In certain embodiments, an additive reservoir 130 is operably coupled to the process chamber 100. The additive reservoir 130 has a supply line 135 that introduces the additive into the wetting solution supply line 125 prior to the wetting solution being introduced into the process chamber 100. There is a valve 134 positioned along the additive supply line 135 that can be opened and closed to enable the additive to flow and prevent the additive from flowing, respectively. Control of the valve 134 can be performed manually or automatically by a controller. In order for the controller to control operation of the valve 134, the valve 134 must be operably coupled to the controller.

The additive is a surfactant that, when combined with the wetting solution, lowers the surface tension of the wetting solution thereby allowing easier spreading of the wetting solution. When used, the additive is combined and mixed with the wetting solution prior to the wetting solution being introduced into the process chamber 100 in order to enhance the ability of the wetting solution to remove particles and/or fluid that is trapped within the deep wells on the substrate surfaces. In the exemplified embodiment, the additive mixes or combines with the wetting solution at some point between the flowmeter 123 and the process chamber 100. However, the invention is not so limited and the additive and wetting solution may be mixed or combined at other locations along the wetting solution supply line 125, such as prior to the flowmeter 123.

The process chamber 100 is also provided with a drain 136 for removal of the wetting solution, additive and any other liquid that is introduced into the process chamber 100 during the priming method. The drain 136 may be a quick dump or a controlled drain. There is a valve 137 along the drain line that must be opened in order to activate draining of the liquid from the process chamber 100. Operation of the valve 137 is achieved either manually or automatically via operable coupling to the controller.

As described above, the sensors, including the pressure sensor 111, the liquid level sensor 113 and the temperature sensor 115 are all operably coupled to the controller so that the entire method described below can be achieved automatically. In other words, as will be described in more detail below, the vacuum pump 110 will operate to achieve specific sub-atmospheric pressures that are pre-determined and programmed into the controller, such as the less than 10 Torr described above. The pressure sensor 111 will monitor the pressure within the process chamber 100 and communicate with the controller to ensure that the appropriate pressure is achieved and maintained as necessary. Similarly, the liquid level sensor 113 and the temperature sensor 115 will also communicate with the controller to ensure that the appropriate liquid level and temperature is achieved and maintained as necessary.

Thus, the entire operation of the process chambers 100, 200 and the vacuum prime and vacuum dry processes may be suitably programmed by the controller, which is a microprocessor based controller capable of carrying out the necessary sequence steps. This may include activating the various valves and other equipment ancillary to the processing chamber 100. Using a microprocessor as has been described hereinabove can automate the entire substrate preparation and substrate drying processes that will be described in detail below. Of course, in certain embodiments the controller can be omitted altogether and opening and closing of the valves may be performed manually by a user.

A method of priming substrates having high-aspect ratio trenches for further processing utilizing the process chamber 100 described above will be described below. First, the lid 101 of the process chamber 100 is opened so that at least one substrate, and preferably a batch of substrates, can be loaded into the process chamber 100. The substrates are supported in the process chamber 100. At the time that the substrates are loaded into the process chamber 100, the process chamber 100 has a gaseous atmosphere in ambient conditions. After loading of the substrates into the process chamber 100, the lid 101 is closed thereby sealing the process chamber 100. In certain embodiments, the lid 101 is connected to the process chamber 100 with gaskets so that the process chamber 100 can be flange sealed.

Once the process chamber 100 is sealed, the valve 119 is opened and the vacuum pump 110 begins evacuating the process chamber 100 of its gaseous atmosphere. The valve 119 remains opened until a first sub-atmospheric pressure is achieved within the process chamber 100. The first sub-atmospheric pressure is less than 10 Torr, and in certain embodiments can be between 1 Torr and 7 Torr. The gaseous atmosphere within the process chamber 100 is evacuated at a rate such that the desired sub-atmospheric pressure is reached in approximately five minutes, although less time is possible. It is necessary that the vacuum not be pulled too quickly to prevent damage to the substrates within the process chamber 100. Opening of the valve 119 can be achieved automatically via the controller as described above. Upon reaching the sub-atmospheric pressure, pressure value data will be transmitted to the controller from the pressure sensor 113 and the controller will cause the valve 119 to close.

Upon reaching the desired sub-atmospheric pressure, the sub-atmospheric pressure is maintained for a period of approximately three to five minutes in order to adequately remove all of the air and gas from the high-aspect ratio trenches of the substrates. The sub-atmospheric pressure will remove air pockets from the trenches so that the wetting solution can fill and remove residue from the trenches upon introduction of the wetting solution into the process chamber 100 as described below.

After the first sub-atmospheric pressure is achieved and maintained for the time period noted above, the wetting solution will begin being introduced into the process chamber 100 by opening the valves 124, 126. A user can visualize the pressure in the process chamber 100 on the display 112 and manually open the valves 124, 126 at such time after the first sub-atmospheric pressure is achieved and held for the desired time period. Alternatively or additionally, the pressure sensor 111 can be operably connected to the controller as described above so that when the pressure within the process chamber 100 reaches the first sub-atmospheric pressure and the first sub-atmospheric pressure is maintained for a predetermined amount of time (i.e., 3-5 minutes), the valves 124, 126 are automatically opened by the controller.

Upon opening of the valves 124, 126, the wetting solution will begin being introduced into the process chamber 100. As the wetting solution enters into the process chamber 100, it primes the recently vacated surfaces features of the substrate. As discussed above, the flow rate of the wetting agent can be monitored and varied by the flowmeter 123. The flow rate of the wetting solution is dependent upon the pressure level within the process chamber 100 and the amount of fluid or wetting solution already present in the process chamber 100. In certain embodiments, the wetting solution is introduced into the process chamber 100 at a substantially constant flow rate. However, in certain other embodiments the flow rate of the wetting solution is varied during introduction of the wetting solution into the process chamber 100. Specifically, the flow rate of the wetting solution can be increased over time as the wetting solution is introduced into the process chamber 100. Increasing the flow rate of the wetting solution can include gradually increasing the flow rate of the wetting solution over time. Alternatively, increasing the flow rate of the wetting solution can include introducing the wetting solution at a first slower flow rate and then subsequently increasing the flow rate to a second, faster flow rate such that the increase is immediate rather than gradual. In certain embodiments, the flow rate of the wetting solution is varied between 5-15 gallons per minute or held constant at a rate in the range of 5-15 gallons per minute.

In certain embodiments, the wetting solution is introduced into the process chamber 100 at ambient temperature, or approximately between 20-25° C. However, in certain other embodiments the wetting solution can be heated by the heater 122 prior to being introduced into the process chamber 100 in order to avoid thermal shock to the substrates within the process chamber 100.

As the wetting solution enters into the process chamber 100, the wetting solution will immediately vaporize and reduce the temperature within the process chamber 100. The vapor will begin to depressurize the process chamber 100. However, it is desirable to maintain the sub-atmospheric pressure during the entire step of introducing the wetting solution into the process chamber 100 so that the air pockets within the trenches are evacuated to enable the wetting solution to penetrate and fill the trenches. In other words, as the wetting solution begins to be introduced into the process chamber 100, some portions of the process chamber 100 will be filled with the liquid wetting solution and other portions of the process chamber 100 will remain devoid of the liquid wetting solution. As the wetting solution begins to fill the process chamber 100, the substrates will be positioned within the process chamber 100 so that portions of the substrates are covered by the wetting solution and other portions are free of the wetting solution and exposed to the atmosphere within the process chamber 100. Thus, in order to ensure that the entirety of the substrate surface and all of the trenches remain devoid of air pockets, the process chamber 100 must remain in a sub-atmospheric pressure during the entirety of the introduction of the wetting solution into the process chamber 100. Thus, the vacuum pump continues to evacuate air from the process chamber 100 during the step of introducing the wetting solution into the process chamber 100 so that the portions of the substrate that are not immersed in the liquid remain in the vacuum or sub-atmospheric pressure environment of the process chamber 100 during introduction of the wetting solution into the process chamber 100. In this way, the exposed trenches remain devoid of air pockets during the introduction of the wetting solution so that the wetting solution can fill the trenches.

In order to achieve the above and maintain a sub-atmospheric pressure within the process chamber 100 during introduction of the wetting solution into the process chamber 100, the valve 119 is opened, at least intermittently, and the vacuum pump 110 continues to evacuate gas and vapor from the process chamber 100 during the step of introducing the wetting solution into the process chamber 100. As such, during the step of introducing the wetting solution into the process chamber 100, the process chamber 100 is maintained at a second sub-atmospheric pressure. In certain embodiments, the second sub-atmospheric pressure is substantially equal to the first sub-atmospheric pressure. However, the invention is not so limited and in certain other embodiments the second sub-atmospheric pressure is a sub-atmospheric pressure that is between the first sub-atmospheric pressure and atmospheric pressure (i.e., 760 Torr).

The wetting solution is introduced into the process chamber 100 until the substrate is immersed in the wetting solution. In certain embodiments, the substrate is immersed in the wetting solution when the substrate is completely submerged in the wetting solution. It is desirable to stop introduction of the wetting solution into the process chamber 100 just as the substrate becomes fully submerged. Thus, the maximum liquid level 150 is the level of the wetting solution that corresponds with the substrate being completely submerged in the wetting solution. As the wetting agent reaches the maximum liquid level 150, the liquid level sensor 113 transmits this data to the controller so that the controller can close the valves 124, 126 and prohibit flow of the wetting solution into the process chamber 100.

Furthermore, it should be understood that the controller is constantly monitoring the pressure level within the process chamber 100. Thus, the vacuum pump 110 can be intermittently turned on and off by opening and closing the valve 119 throughout the step of introducing the wetting solution into the process chamber 100. In this manner, the controller can ensure that the pressure is maintained at the second sub-atmospheric pressure during the entire step of introducing the wetting solution into the process chamber 100. It should be understood that the second sub-atmospheric pressure may vary as the wetting solution is introduced into the process chamber 100 while the vacuum pump 110 continues to evacuate air from the process chamber 100.

After the substrate is completely immersed in the wetting solution, the vacuum pump 110 is turned off by closing the valve 119 and the wetting solution is prevented from continuing to enter into the process chamber 100 by closing the valves 124, 126. At this time, the process chamber 100 is restored to atmospheric pressure while the substrate remains immersed in the wetting solution. After atmospheric pressure is restored to the process chamber 100, the substrate is removed from the process chamber 100 and from the wetting solution. In certain embodiments, the substrate is removed from the process chamber 100 prior to draining the wetting solution from the process chamber 100. This enables trace amounts of the wetting solution to be retained within the high-aspect ratio trenches of the substrate via surface tension. Retaining amounts of the wetting solution within the high-aspect ratio trenches of the substrate protects the substrate by preventing residue and other contaminants from entering into the trenches.

Once the substrates are removed from the process chamber 100, the substrates are prepared and primed for further processing. The process chamber 100 can be drained of the wetting solution and any other liquids by opening the valve 137. The method of priming substrates described above is a process that takes approximately ten minute or less from the time of sealing the process chamber 100 to removal of the substrates from the process chamber 100.

After being primed as described above, the substrates are prepared for further processing. Thus, the substrates can undergo any process sequences as would be known to persons skilled in the art such as, for example without limitation, physical vapor deposition, chemical vapor deposition, photolithography, plasma etch, rapid thermal processing, chemical-mechanical planarization and the like. These process sequences may be referred to herein as intermediate process sequences. The invention is not to be in any way limited by the specific intermediate process sequences that the substrates undergo after the priming process. In other words, the substrates can undergo any process sequences now known or later discovered after the priming process described above is completed.

After the substrates have undergone the at least one intermediate process sequence (and likely many intermediate process sequences) after being primed as described above, the substrates must undergo a process to remove bulk moisture from the substrate. Bulk moisture removal is done by a process that dries the substrates to typical semiconductor standards. In certain embodiments, this bulk moisture removal can be done during a spin dry process. In certain other embodiments, the bulk moisture is removed during a surface-tension gradient drying technique. One type of a surface-tension gradient drying technique that may be used is a Marangoni-type process whereby the substrate is positioned within a process tank that is filled with a liquid such as deionized water. An isopropyl alcohol (IPA) vapor is fed into an upper interior space of the deionized water and the deionized water is slowly withdrawn. The IPA lowers the surface tension of the deionized water thereby effectively removing the deionized water from the surface of the substrate. In this way, a substantial amount of the moisture, which may be referred to as the bulk moisture, is removed from the substrate.

As discussed in detail above, all of the moisture must be removed from the substrate in order to avoid streaking and potential damage or contamination to the substrate and its circuitry. However, although the bulk moisture removal processes described above dry the substrates to typical semiconductor standards, they tend to leave excess moisture on the substrate surface, and particularly within the high aspect ratio trenches of the substrates. In order to remove the remainder of the moisture, the vacuum drying method described hereinafter below is used. In describing the vacuum drying method, a process tank 200 and its components will be described. It should be understood that many of the components of the process tank 200 are similar to or the same as corresponding components of the process tank 100. Those components of the process tank 200 will be described using the same reference numerals as the corresponding components of the process tank 100 except that the 200-series of numbers will be used.

The process tank 200 is very similar to the process tank 100 except that the process tank 200 is not operably coupled to a wetting solution reservoir or an additive reservoir. Rather, a carrier gas reservoir 220 is operably coupled to the process tank 200 by a supply line 225. There is a heater 222 positioned along the supply line 225 between the carrier gas reservoir 220 and the process tank 220. Furthermore, the supply line 225 comprises a valve 226 that opens and closes to allow and prevent the carrier gas from being introduced into the process chamber 200, respectively. The valve 226 is operably coupled to a controller for automating the opening and closing of the valve 226 as has been described in detail above with respect to the valves 124, 126. The supply line 225 is also coupled to a flowmeter 223 that is positioned between the heater 222 and the valve 226.

Furthermore, similar to the process chamber 100, the process chamber 200 contains a temperature sensor 215 that is operably coupled to a display 216 for displaying the temperature within the process chamber 200 and a pressure sensor 213 that is operably coupled to a display 214 for displaying the pressure within the process chamber 200. In certain embodiments, the temperature sensor 215 and the pressure sensor 213 are operably coupled to the controller so that temperature and pressure data can be transmitted to the controller. This enables the controller to automate the opening and closing of valves to ensure that the pressure and temperature within the process chamber 200 is proper in accordance with the drying process. Furthermore, in certain embodiments the process chamber 200 has wall heaters for heating the process chamber 200. However, the invention is not limited to the process chamber 200 being heated and in certain other embodiments the wall heaters are omitted.

The vacuum drying process will now be described below. After bulk moisture is removed from the substrate as described above, the substrate is supported in the process chamber 200 (second process chamber). At the moment that the substrate is placed in the process chamber 200, the process chamber 200 has a gaseous atmosphere. Once the substrates are supported by the process chamber 200, the lid 201 is closed, thereby sealing the process chamber 200. After the process chamber 200 is sealed, the valve 219 is opened and the vacuum pump 210 begins to operate to evacuate the air from the process chamber 200.

The vacuum pump 210 continues to operate until a first sub-atmospheric pressure is achieved within the process chamber 200. In certain embodiments the first sub-atmospheric pressure is equal to or less than 10 Torr. After the first sub-atmospheric pressure is reached, the valve 219 is closed and the process chamber 200 maintains the first sub-atmospheric pressure for a period of time equal to approximately five minutes or less. This enables the vacuum to have sufficient time to pull any liquid molecules off of the substrate surfaces and out of the substrate trenches. Once the first sub-atmospheric pressure has been maintained for an adequate period of time, the valve 226 is opened and the carrier gas begins to be introduced into the process chamber 200. The carrier gas is heated prior to entering the process tank 200 by the heater 222. In certain embodiments, the carrier gas is heated to be between 50-70° C. The heated carrier gas enables the process chamber 200 to more effectively draw moisture from the substrate while preventing surface spotting.

In certain embodiments, the carrier gas is nitrogen gas (N₂). However, the invention is not so limited and the carrier gas can be other gases such as any noble gas or CO₂. The invention is not to be in any way limited by the particular carrier gas that is introduced into the process tank 200 during the drying method. Furthermore, in certain embodiments the carrier gas may carry a polar organic compound to further facilitate drying of moisture from the high-aspect ratio trenches of the substrate. In certain embodiments, the polar organic compound is isopropyl alcohol (IPA).

Furthermore, in certain embodiments the carrier gas is introduced into the process chamber 200 at a constant flow rate. However, the invention is not so limited and in certain other embodiments the flow rate of the gas being introduced into the process chamber 200 can vary via the flowmeter 223. In certain embodiments, varying the flow rate of the carrier gas involves increasing the flow rate over time as the gas is introduced into the process chamber 200. Increasing the flow rate of the carrier gas can include gradually increasing the flow rate of the carrier gas. Alternatively increasing the flow rate of the carrier gas can include introducing the carrier gas at a first slower flow rate and then subsequently increasing the flow rate to a second, faster flow rate such that the increase is immediate rather than gradual.

The atmospheric pressure in the process chamber 200 is maintained at a second sub-atmospheric pressure during the introduction of the heated carrier gas into the process chamber 200. Thus, the valve 219 can be intermittently opened and closed in order to maintain the second sub-atmospheric pressure throughout the vacuum dry process. The second sub-atmospheric pressure can be the same as the first sub-atmospheric pressure, or it can be a pressure that is between the first sub-atmospheric pressure and atmospheric pressure.

After the heated carrier gas has been introduced into the process chamber 200 for a sufficient period of time, the valve 226 is closed so that the heated carrier gas can no longer enter into the process chamber 200 and the valve 219 is closed so that the vacuum pump 210 no longer pulls air from the process chamber 200. Then, the process chamber 200 is allowed to equalize such that the pressure within the process chamber 200 is restored to atmospheric pressure. At this time, the substrates are sufficiently dry and can be removed from the process chamber 200. The entirety of the method of drying substrates described herein takes approximately ten minutes or less from the moment of sealing the process chamber 200 to removal of the substrates from the process chamber 200.

Although the method has been described above as being a single process that includes the vacuum prime process, an intermediate process sequence and the vacuum dry process, the vacuum prime and vacuum dry processes need not always be used in the same process sequence. In certain embodiments, the vacuum prime process can be used to prime the substrate surfaces prior to further processing without ending the process sequence with the vacuum dry process. Furthermore, in other embodiments the vacuum dry process described herein can be used to dry the substrates without using the vacuum prime process to prime the substrates prior to further processing. In other words, the vacuum prime and vacuum dry processes described herein are independent and mutually exclusive processes that can be performed one without the other.

In an alternative embodiment, rather than having a first process chamber 100 for vacuum priming of the substrate and a second process chamber 200 for vacuum drying of the substrate, a single process chamber may be used for both the priming and drying processes. Furthermore, it should be understood that the process chambers 100, 200 are made of a stainless steel material, but the invention is not so limited and the process chambers 100, 200 may be constructed of any material that is suitable for use under vacuum conditions as described above. Specifically, the material of the process chambers 100, 200 must be capable of remaining sealed to sustain a sub-atmospheric pressure of less than 10 Torr without degrading or otherwise becoming inoperable.

While the foregoing description and drawings represent the exemplary embodiments of the present invention, it will be understood that various additions, modifications and substitutions may be made therein without departing from the spirit and scope of the present invention as defined in the accompanying claims. In particular, it will be clear to those skilled in the art that the present invention may be embodied in other specific forms, structures, arrangements, proportions, sizes, and with other elements, materials, and components, without departing from the spirit or essential characteristics thereof. One skilled in the art will appreciate that the invention may be used with many modifications of structure, arrangement, proportions, sizes, materials, and components and otherwise, used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims, and not limited to the foregoing description or embodiments.

What is claimed is:

1. A method of priming substrates having high-aspect ratio trenches for further processing, the method comprising:
a) supporting at least one substrate having high-aspect ratio trenches in a process chamber having a gaseous atmosphere;
b) sealing the process chamber;
c) vacuuming the process chamber to achieve a first sub-atmospheric pressure within the process chamber after step b) and prior to step d), the first sub-atmospheric pressure being equal to or less than 10 Torr and being maintained, prior to step d), for a period of time sufficient to remove all air and gas from the high-aspect ratio trenches;
d) introducing a wetting solution into the process chamber while maintaining the process chamber at a second sub-atmospheric pressure until the substrate is immersed in the wetting solution, the second sub-atmospheric pressure being at a level sufficient to ensure that the high-aspect ratio trenches remain devoid of air and gas such that the wetting solution fills the high-aspect ratio trenches without formation of air pockets, wherein the wetting solution is heated during its introduction;
e) restoring the process chamber to atmospheric pressure while the substrate remains immersed in the wetting solution; and
f) removing the substrate from the wetting solution,
wherein during steps c) and d), measuring the pressure within the process chamber with a pressure sensor that is operably coupled to a controller, the controller configured to achieve and maintain the first and second sub-atmospheric pressures.

2. The method of claim 1 wherein the high aspect ratio trenches of the substrate have a depth to width ratio that is greater than 5:1.

3. The method of claim 1 wherein trace amounts of the wetting solution are retained within the high-aspect ratio trenches of the substrate via surface tension.

4. The method of claim 1 wherein the period of time is approximately three to five minutes.

5. The method of claim 1 wherein the first sub-atmospheric pressure is between 1 Torr to 7 Torr.

6. The method of claim 1 wherein the wetting solution is selected from the group consisting of DIW, SC1, SC2, HF, ozonated water and combinations thereof.

7. The method of claim 1 wherein the first sub-atmospheric pressure is substantially equal to the second sub-atmospheric pressure.

8. The method of claim 1 wherein the second sub-atmospheric pressure is between the first sub-atmospheric pressure and atmospheric pressure.

9. The method of claim 1 wherein step d) comprises introducing the wetting solution into the process chamber at a substantially constant flow rate.

10. The method of claim 1 wherein step d) comprises varying a flow rate of the wetting solution being introduced into the process chamber during said introduction.

11. The method of claim 10 wherein step d) comprises increasing the flow rate of the wetting solution being introduced into the process chamber during said introduction.

12. The method of claim 1 wherein upon completion of step f), amounts of the wetting solution remain in the high-aspect ratio trenches of the substrate.

13. A method of drying substrates having high-aspect ratio trenches comprising:
a) supporting at least one substrate having high-aspect ratio trenches in a process chamber having a gaseous atmosphere;
b) sealing the process chamber;
c) vacuuming the process chamber to achieve a first sub-atmospheric pressure within the process chamber, the first sub-atmospheric pressure being equal to or less than 10 Torr; and
d) introducing a heated gas into the process chamber while maintaining the process chamber at a second sub-atmospheric pressure, wherein a flow rate of the heated gas being introduced into the process chamber is varied during said introduction, the heated gas carrying a polar organic compound that facilitates drying of moisture from the high-aspect ratio trenches of the substrate;
wherein the second sub-atmospheric pressure is different from the first sub-atmospheric pressure and is between the first sub-atmospheric pressure and atmospheric pressure.

14. The method of claim 13 wherein step d) comprises increasing the flow rate of the heated gas being introduced into the process chamber during said introduction.

15. The method of claim 13 wherein the polar organic compound is isopropyl alcohol (IPA).

16. The method of claim 13 further comprising removing bulk moisture from the substrate using a surface-tension gradient drying technique prior to step a).

17. A method of processing substrates having high aspect ratio trenches, the method comprising:
a) supporting at least one substrate having high-aspect ratio trenches in a first process chamber having a gaseous atmosphere;
b) sealing the first process chamber;
c) vacuuming the first process chamber to achieve a first sub-atmospheric pressure within the first process chamber after step b) and prior to step d), the first sub-atmospheric pressure being equal to or less than 10 Torr and being maintained, prior to step d), for a period of time sufficient to remove all air and gas from the high-aspect ratio trenches;
d) introducing a wetting solution into the process chamber while maintaining the first process chamber at a second sub-atmospheric pressure until the substrate is immersed in the wetting solution, the second sub-atmospheric pressure being at a level sufficient to ensure that the high-aspect ratio trenches remain devoid of air and gas such that the wetting solution fills the high-aspect ratio trenches without formation of air pockets;
e) restoring the process chamber to atmospheric pressure while the substrate remains immersed in the wetting solution;
f) removing the substrate from the wetting solution;
g) performing at least one process sequence to the substrate;
h) removing bulk moisture from the substrate;
i) supporting the substrate in a second process chamber having a gaseous atmosphere;
j) sealing the second process chamber;
k) vacuuming the second process chamber to achieve a third sub-atmospheric pressure within the second process chamber; and
l) introducing a heated gas into the process chamber while maintaining the process chamber at a fourth sub-atmospheric pressure, thereby removing residual moisture from the high aspect ratio trenches of the substrate;
wherein the fourth sub-atmospheric pressure is different from the third sub-atmospheric pressure and is between the third sub-atmospheric pressure and atmospheric pressure.

18. The method of claim 17 wherein step h) comprises removing the bulk moisture from the substrate using a surface-tension gradient drying technique.

19. The method of claim 17 wherein step l) comprises the heated gas carrying a polar organic compound that facilitates removal of the residual moisture from the high-aspect ratio trenches of the substrate.

20. The method of claim 19 wherein the polar organic compound is isopropyl alcohol (IPA).
